(19) United States
(12) Patent Application Publication
(10) Pub. No.: US 2015/0061753 A1
(43) Pub. Date: Mar. 5, 2015

(54) SIGNAL OUTPUT CIRCUIT AND SIGNAL OUTPUT METHOD

(71) Applicant: Sony Corporation, Tokyo (JP)

(72) Inventor: Yasufumi HINO, Kanagawa (JP)

(21) Appl. No.: 14/457,218

(22) Filed: Aug. 12, 2014

(30) Foreign Application Priority Data
Sep. 4, 2013 (JP) 2013-182669

(51) Int. Cl. H03K 17/687

(52) U.S. Cl. CPC H03K 17/6871; H03K 2217/0054
USPC 327/434

(57) ABSTRACT

A signal output circuit includes: an output buffer including a first terminal configured to output a first output signal; a first output terminal; a first switch inserted on a signal path from the first terminal to the first output terminal; and a second switch configured to transmit a predetermined voltage to the first output terminal when being turned on.

### CROSS REFERENCES TO RELATED APPLICATIONS

The present application claims priority to Japanese Priority Patent Application JP 2013-182669 filed in the Japan Patent Office on Sep. 4, 2013, the entire content of which is hereby incorporated by reference.

### BACKGROUND

The present disclosure relates to a signal output circuit configured to output a signal, and a signal output method used for such a signal output circuit.

In signal transmission between a plurality of large-scale integrated circuits (LSIs), AC coupling (capacitive coupling) is often used. Such AC coupling allows a transmission circuit to transmit an AC component of a signal to a reception circuit without transmitting a DC component of the signal. Therefore, even if a DC level of the transmission circuit is different from that of the reception circuit, it is possible to easily transmit a signal.

On the other hand, when an excessively large voltage is transiently generated on the transmission circuit, for example, at power application, such a voltage may be transmitted to the reception circuit through the AC coupling. In such a case, the voltage transmitted to the reception circuit may exceed the rating of the reception circuit, leading to a possibility of occurrence of degradation in properties or device failure in the reception circuit. In particular, in recent years, an LSI manufacturing process has increasingly become finer, and a rating voltage has been gradually lowered. Hence, degradation in properties or the like may easily occur in the reception circuit due to the transient signal transferred to the reception circuit.

Various techniques have been disclosed in order to reduce such occurrence of degradation in properties or the like in the reception circuit. For example, Japanese Unexamined Patent Application Publication No. 2007-214688 discloses a technique that protects a device in an analog frontend circuit (a reception circuit) by providing an RC filter between a buffer circuit (a transmission circuit), which is AC-coupled to the analog frontend circuit, and a power source.

### SUMMARY

In this way, it is desired to reduce a possibility of occurrence of degradation in properties or device failure in the reception circuit during signal transmission between a plurality of LSIs.

It is desirable to provide a signal output circuit and a signal output method capable of reducing a possibility of occurrence of degradation in properties or device failure in a reception circuit.

According to an embodiment of the present disclosure, there is provided a signal output circuit, including: an output buffer including a first terminal configured to output a first output signal; a first output terminal; a first switch inserted on a signal path from the first terminal to the first output terminal; and a second switch configured to transmit a predetermined voltage to the first output terminal when being turned on.

According to an embodiment of the present disclosure, there is provided a signal output method, including: outputting a first output signal from a first terminal of an output buffer; controlling a first switch to be off for a predetermined period, the first switch being inserted on a signal path from the first terminal to a first output terminal, and controlling a second switch to be on for the predetermined period, the second switch being configured to supply a predetermined voltage to the first output terminal when being turned on; and thereafter performing operation of turning on the first switch and operation of turning off the second switch.

In the signal output circuit according to the above-described embodiment of the present disclosure, the first output signal is transmitted from the first terminal of the output buffer to the first output terminal, and is outputted from the first output terminal. The first switch is inserted on the signal path from the first terminal to the first output terminal, and a second switch is provided, the second switch being configured to transmit a predetermined voltage to the first output terminal when being turned on.

In the signal output method according to the above-described embodiment of the present disclosure, the first switch is controlled to be off while the second switch is controlled to be on for the predetermined period. Thereafter, operation of turning on the first switch and operation of turning off the second switch are performed.

According to the signal output circuit of the above-described embodiment of the present disclosure, since the first switch and the second switch are provided, it is possible to reduce a possibility of occurrence of degradation in properties or device failure in the reception circuit.

According to the signal output method of the above-described embodiment of the present disclosure, since the first switch is controlled to be off while the second switch is controlled to be on for a predetermined period, and thereafter operation of turning on the first switch and operation of turning off the second switch are performed. It is therefore possible to reduce a possibility of occurrence of degradation in properties or device failure in the reception circuit.

It is to be noted that the effects described herein are not necessarily limitative, and any of other effects described in this disclosure may be shown.

It is to be understood that both the foregoing general description and the following detailed description are exemplary, and are intended to provide further explanation of the technology as claimed.

Additional features and advantages are described herein, and will be apparent from the following Detailed Description and the figures.

### BRIEF DESCRIPTION OF THE FIGURES

The accompanying drawings are included to provide a further understanding of the disclosure, and are incorporated in and constitute a part of this specification. The drawings illustrate embodiments and, together with the specification, serve to explain the principles of the technology.

FIG. 1 is a block diagram illustrating an exemplary configuration of a reception unit according to an embodiment of the present disclosure.

FIG. 2A is a circuit diagram illustrating an exemplary configuration of a switch illustrated in FIG. 1.

FIG. 2B is a circuit diagram illustrating another exemplary configuration of the switch illustrated in FIG. 1.

FIG. 2C is a circuit diagram illustrating still another exemplary configuration of the switch illustrated in FIG. 1.

FIG. 3 is a timing waveform diagram illustrating an example of operation of the reception unit illustrated in FIG. 1.

FIG. 4 is a block diagram illustrating an exemplary configuration of a reception unit according to a comparative example.

FIG. 5 is a timing waveform diagram illustrating an example of operation of the reception unit illustrated in FIG. 4.

FIG. 6 is a timing waveform diagram illustrating an example of operation of a reception unit according to a modification.

FIG. 7 is a block diagram illustrating an exemplary configuration of a reception unit according to another modification.

FIG. 8 is a block diagram illustrating an exemplary configuration of a unit according to still another modification.

### DETAILED DESCRIPTION

Hereinafter, an embodiment of the present disclosure will be described in detail with reference to accompanying drawings.

[Exemplary Configuration]

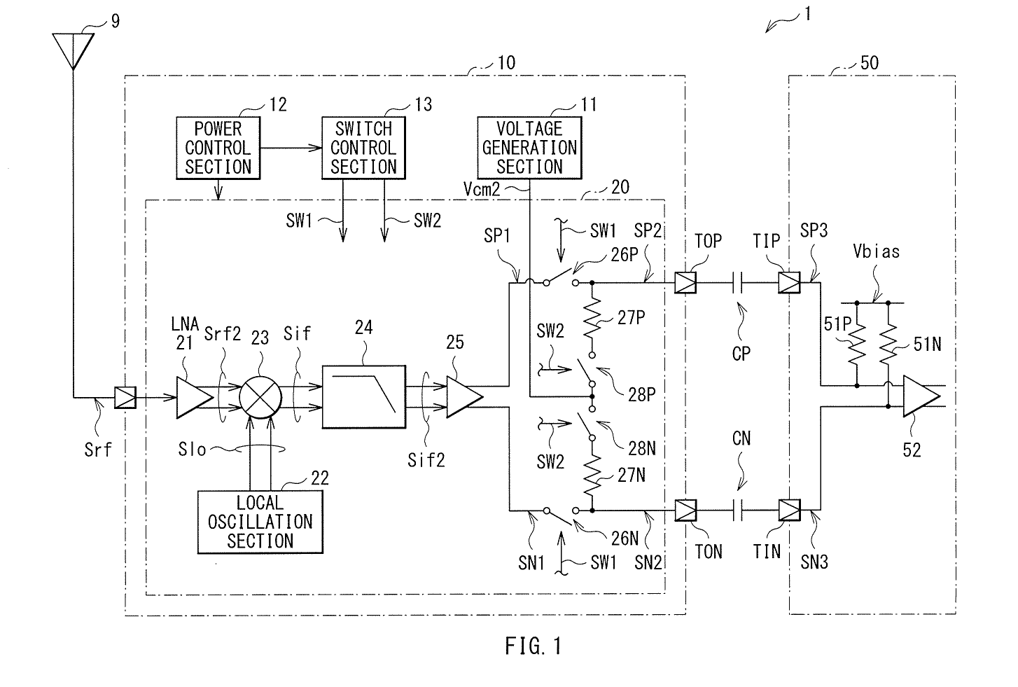

FIG. 1 illustrates an exemplary configuration of a reception unit according to an embodiment. This reception unit 1 receives radio signals. It is to be noted that since a signal transmission circuit and a signal transmission method according to the embodiment of the disclosure are embodied by this embodiment, they are described together.

The reception unit 1 includes a radio frequency (RF) circuit 10 and a demodulation circuit 50. The RF circuit 10 generates a differential signal through downconversion, etc. based on a signal Srf supplied from an antenna 9, and supplies the differential signal to the demodulation circuit 50 via capacitors CP and CN. Specifically, the RF circuit 10 supplies the differential signal to the demodulation circuit 50 through AC coupling using the capacitors CP and CN. The demodulation circuit 50 is a circuit that demodulates a radio signal based on the differential signal supplied from the RF circuit 10. In this exemplary case, each of the RF circuit 10 and the demodulation circuit 50 is configured of one chip.

The RF circuit 10 includes an RF section 20, a voltage generation section 11, a power control section 12, and a switch control section 13. The RF section 20 includes a low noise amplifier (LNA) 21, a local oscillation section 22, a mixer 23, a filter 24, an output buffer 25, switches 26P and 26N, resistors 27P and 27N, and switches 28P and 28N.

The LNA 21 is a circuit that amplifies the signal Srf supplied from the antenna 9 while suppressing noise generation, and outputs the amplified signal as a differential signal Srf2. In the reception unit 1, the LNA 21 provided in a first stage makes it possible to raise a signal-to-noise ratio (S/N ratio) of the reception unit 1 as a whole. Consequently, the reception unit 1 is allowed to receive a weak radio wave.

The local oscillation section 22 is an oscillation circuit that generates a differential signal Slo having a frequency equal to that of a carrier wave of radio communication, and, for example, may be configured of a frequency synthesizer using a phase locked loop (PLL).

The mixer 23 multiplies the differential signal Srf2 by the differential signal Slo to down-convert the differential signal Srf2, and thereby extracts a signal component superimposed on the carrier wave, and outputs the signal component as a differential signal Sif.

The filter 24 is a low-pass filter that generates a differential signal Sif2 through removing an unnecessary frequency component, which is generated with the multiplication by the mixer 23, from the differential signal Sif.

The output buffer 25 is an output interface circuit that generates signals SP1 and SN1 based on the differential signal Sif2. Each of the signals SP1 and SN1 is an analog signal as a differential signal having a common mode voltage set to a voltage Vcm1.

Each of the switches 26P and 26N is a switch that is turned on or off based on a switch control signal SW1, and is, for example, configured of a metal oxide semiconductor (MOS) field effect transistor (FET). The switch 26P has a first end to which a signal SP1 is supplied from the output buffer 25, and a second end that is connected to a first end of the resistor 27P and to a first end of the capacitance element CP via an output terminal TOP of the RF circuit 10. The switch 26N has a first end to which a signal SN1 is supplied from the output buffer 25, and a second end that is connected to a first end of the resistor 27N and to a first end of the capacitance element CN via an output terminal TON of the RF circuit 10.

The resistor 27P has a first end that is connected to the second end of the switch 26P and to a first end of the capacitor CP via the output terminal TOP, and has a second end connected to a first end of the switch 28P. The resistor 27N has a first end that is connected to the second end of the switch 26N and to a first end of the capacitor CN via the output terminal TON, and has a second end connected to a first end of the switch 28N.

Each of the switches 28P and 28N is a switch that is turned on or off based on a switch control signal SW2, and is, for example, configured of a metal oxide semiconductor (MOS) transistor. The switch 28P has a first end connected to the second end of the resistor 27P, and a second end to which a voltage Vcm2 (described later) is supplied from the voltage generation section 11. The switch 28N has a first end connected to the second end of the resistor 27N, and a second end to which the voltage Vcm2 is supplied from the voltage generation section 11. As will be described later, the voltage Vcm2 is a voltage substantially equal to a common mode voltage Vcm1 of the signals SP1 and SN1.

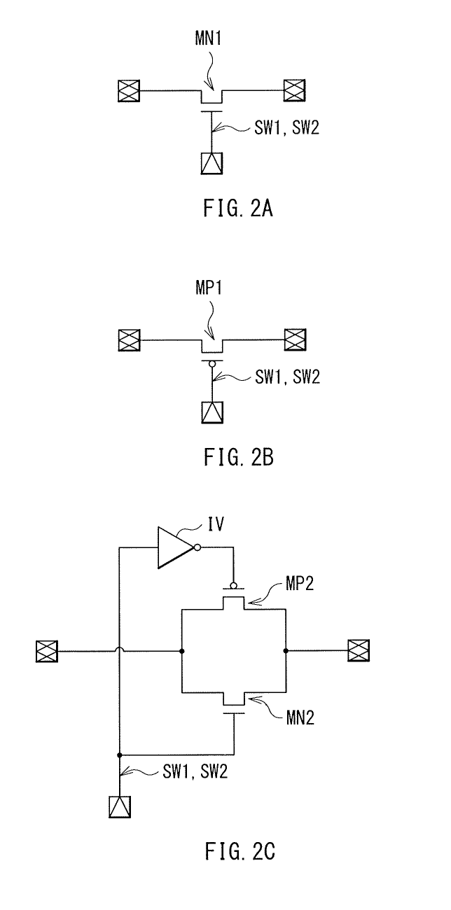

FIGS. 2A to 2C illustrate an exemplary configuration of each of the switches 26P and 26N or each of the switches 28P and 28N. FIG. 2A illustrates an example of the switch configured using an N-type MOS transistor MN1, FIG. 2B illustrates an example of the switch configured using a P-type MOS transistor MP1, and FIG. 2C illustrates an example of the switch configured using a so-called transmission gate.

In FIG. 2A, the switch control signal SW1 or the switch control signal SW2 is applied to a gate of the MOS transistor MN1 so that a drain-source path becomes on or off based on the voltage of the switch control signal SW1 or SW2. Specifically, when the switch control signal SW1 or SW2 is at a high level, the drain-source path becomes on, and when the switch control signal SW1 or SW2 is at a low level, the drain-source path becomes off.

In FIG. 2B, the switch control signal SW1 or SW2 is applied to a gate of the MOS transistor MP1 so that a drain-source path becomes on or off based on voltage of the switch control signal SW1 or SW2. Specifically, when the switch control signal SW1 or SW2 is at a low level, the drain-source path becomes on, and when the switch control signal SW1 or SW2 is at a high level, the drain-source path becomes off.

In a configuration of FIG. 2C, the switch is configured by an N-type MOS transistor MN2, a P-type MOS transistor MP2, and an inverter IV. In this exemplary case, a source of the N-type MOS transistor MN2 is connected to a source of the P-type MOS transistor MP2. Similarly, a drain of the N-type MOS transistor MN2 is connected to a drain of the P-type MOS transistor MP2. The inverter IV has an input terminal connected to a gate of the N-type MOS transistor MN2, and an output terminal connected to a gate of the P-type MOS transistor MP2. According to such a configuration, the switch control signal SW1 or SW2 is applied to the gate of the MOS transistor MN2 so that a path between both ends becomes on or off based on voltage of the switch control signal SW1 or SW2. Specifically, when the switch control signal SW1 or SW2 is at a high level, the path between both ends becomes on, and when the switch control signal SW1 or SW2 is at a low level, path between both ends becomes off.

Each of the switches 26P, 26N, 28P, and 28N may include any one of the configurations of FIGS. 2A to 2C. The following description is made assuming that such four switches are each configured using the configuration of FIG. 2C.

The voltage generation section 11 is a circuit that generates the voltage Vcm2, and supplies the voltage Vcm2 to the second end of each of the switches 28P and 28N. In this exemplary case, the voltage Vcm2 is a voltage that is substantially equal to the common mode voltage Vcm1 of the output signals SP1 and SN1 of the output buffer 25.

The power control section 12 controls power supply to the RF section 20. Specifically, for example, the power control section 12 may determine whether or not power supply to the RF section 20 is to be performed based on undepicted received signal strength indication (RSSI), and may control power supply to the RF section based on the results of such determination. Furthermore, the power control section 12 may have a function of generating a control signal indicating whether or not power supply to the RF section 20 is being performed, and supplying the control signal to the switch control section 13.

The switch control section 13 generates the switch control signals SW1 and SW2 based on a control signal supplied from the power control section 12 to control on-off operation of each of the switches 26P, 26N, 28P, and 28N. Specifically, as will be described later, the switch control section 13 sets each of the switches 26P and 26N to the off state, and sets each of the switches 28P and 28N to the on state, and then the power control section 12 starts power supply to the RF section 20. After a predetermined period has passed from start of the power supply to the RF section 20 by the power control section 12, the switch control section 13 changes each of the switches 28P and 28N to the off state, and then changes the switches 26P and 26N to the on state. Consequently, in the reception unit 1, as will be described later, even if the output signals SP1 and SN1 of the output buffer 25 are each transiently varied in response to application of power to the RF section 20, it is possible to suppress influence of such signal variation on a subsequent-stage circuit (the demodulation circuit 50).

The capacitors CP and CN are provided for AC coupling of the RF circuit 10 and the demodulation circuit 50. The capacitance element CP has the first end connected to the output terminal TOP of the RF circuit 10, and a second end connected to an input terminal TIP of the demodulation circuit 50. The capacitance element CN has a first end connected to the output terminal TON of the RF circuit 10, and a second end connected to an input terminal TIN of the demodulation circuit 50. Consequently, an AC component of a signal SP2 of the output terminal TOP of the RF circuit 10 is transmitted to the input terminal TIP of the demodulation circuit 50, and an AC component of a signal SN2 of the output terminal TON of the RF circuit 10 is transmitted to the input terminal TIN of the demodulation circuit 50.

The demodulation circuit 50 includes resistors 51P and 51N and an input buffer 52. The resistors 51P and 51N are each a resistor supplying a bias voltage Vbias to an input terminal of the input buffer 52. The resistor 51P has a first end connected to a second end of the capacitor CP via the input terminal TIP of the demodulation circuit 50, and a second end to which the bias voltage Vbias is supplied. The resistor 51N has a first end connected to a second end of the capacitor CN via the input terminal TIN of the demodulation circuit 50, and a second end to which the bias voltage Vbias is supplied. The input buffer 52 is an input interface circuit that receives a signal SP3 of the input terminal TIP and a signal SN3 of the input terminal TIN. In the demodulation circuit 50, for example, an undepicted analog/digital (A/D) converter performs A/D conversion based on an output signal of the input buffer 52, and then an undepicted demodulation section performs demodulation processing.

The output terminals TOP and TON correspond to specific but not limitative examples of “first output terminal” and “second output terminal”, respectively, in an embodiment of the disclosure. The switches 26P and 26N correspond to specific but not limitative examples of “first switch” and “third switch”, respectively, in an embodiment of the disclosure. The switches 28P and 28N correspond to specific but not limitative examples of “second switch” and “fourth switch”, respectively, in an embodiment of the disclosure.

[Operation and Functions]

Operation and functions of the reception unit 1 of this embodiment are now described.

(Summary of Overall Operation)

First, summary of overall operation of the reception unit 1 is described with reference to FIG. 1. The LNA 21 amplifies the signal Srf supplied from the antenna 9, and outputs the amplified signal as a differential signal Srf2. The local oscillation section 22 generates the differential signal Slo having a frequency equal to that of a carrier wave of radio communication. The mixer 23 multiplies the differential signal Srf2 by the differential signal Slo to down-convert the differential signal Srf2, and thereby extracts a signal component superimposed on the carrier wave, and outputs the signal component as the signal Sif. The filter 24 generates the differential signal Sif2 through removing an unnecessary frequency component, which is generated with the multiplication by the mixer 23, from the differential signal Sif. The output buffer 25 generates the signals SP1 and SN1 based on the differential signal Sif2. The switches 26P and 26N are turned on or off based on the switch control signal SW1 to supply the signals SP1 and SN1 to the output terminals TOP and TON, respectively. The switches 28P and 28N are turned on or off based on the switch control signal SW2 to supply the voltage Vcm2 to the output terminals TOP and TON via the resistors 27P and 27N, respectively. The voltage generation section 11 generates the voltage Vcm2. The power control section 12 controls power supply to the RF section 20, and generates the control signal indicating whether or not power supply to the RF section 20 is being performed, and supplies the control signal to the switch control section 13. The switch control section 13 generates the switch control signals SW1 and SW2 based on the control signal supplied from the power control section 12. The RF circuit 10 supplies the signal SP2 of the output terminal TOP to the input terminal TIP of the demodulation circuit 50 through AC coupling via the capacitor CP, and supplies the signal SN2 of the output terminal TON to the input terminal TIN of the demodulation circuit 50 through AC coupling via the capacitor CN.

(Detailed Operation)

When the power control section 12 starts power supply to the RF section 20, the switch control section 13 controls the switches 26P, 26N, 28P, and 28N. This operation is described in detail below.

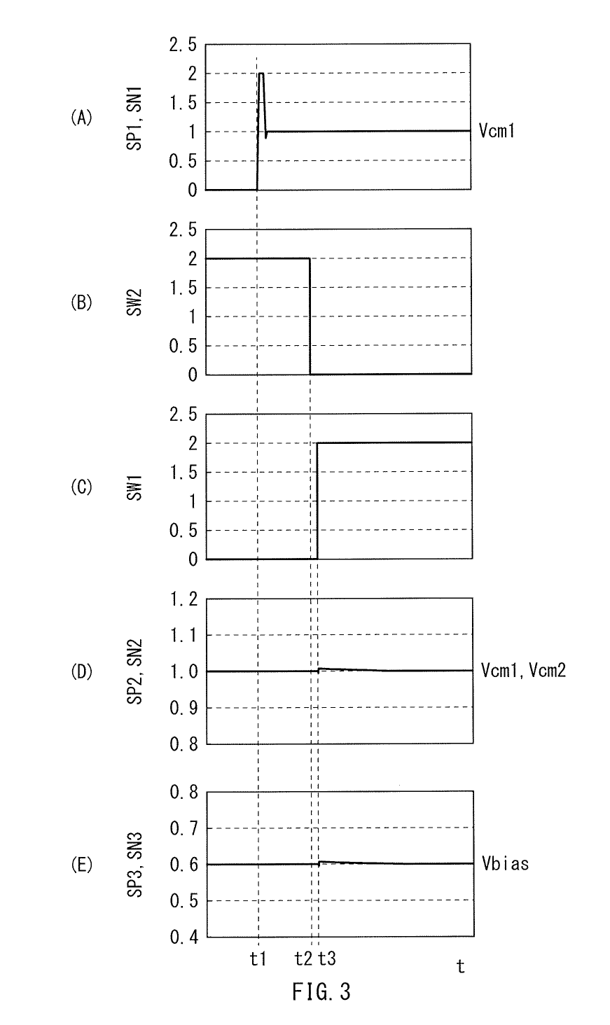

FIG. 3 illustrates operation of the RF section 20 at power application to the RF section 20, where (A) illustrates a waveform of each of the signals SP1 and SN1, (B) illustrates a waveform of the switch control signal SW2, (C) illustrates a waveform of the switch control signal SW1, (D) illustrates a waveform of each of the signals SP2 and SN2, and (E) illustrates a waveform of each of the signals SP3 and SN3. In this exemplary case, the RF circuit 10 may operate at a power voltage of, for example, 2 V, and the demodulation circuit 50 may operate at a power voltage of, for example, 1.2 V. At power application, the signals SP1 and SN1 ((A) of FIG. 3) have waveforms similar to each other, the signals SP2 and SN2 ((D) of FIG. 3) have waveforms similar to each other, and the signals SP3 and SN3 ((E) of FIG. 3) have waveforms similar to each other. In each of (A), (D), and (E) of FIG. 3, therefore, only one waveform is illustrated.

Before timing t1, the power control section 12 suspends power supply to the RF section 20. As a result, the signals SP1 and SN1 each have a voltage of 0 V ((A) of FIG. 3). The voltage generation section 11 generates the voltage Vcm2 (in this exemplary case, 1.0 V), and supplies the voltage Vcm2 to the second end of each of the switches 28P and 28N. The switch control section 13 supplies the low-level switch control signal SW1 to the switches 26P and 26N ((C) of FIG. 3) to turn off each of the switches 26P and 26N, and concurrently supplies the high-level switch control signal SW2 to the switches 28P and 28N ((B) of FIG. 3) to turn on each of the switches 28P and 28N. Consequently, the voltage of each of the signals SP2 and SN2 becomes equal to the voltage Vcm2 ((D) of FIG. 3). The power voltage is supplied to the demodulation circuit 50 that is thereby in an operation state. Consequently, the voltage of each of the signals SP3 and SN3 is set to the bias voltage Vbias (in this exemplary case, 0.6 V) ((E) of FIG. 3).

Subsequently, at timing t1, the power control section 12 starts power supply to the RF section 20. Consequently, in this exemplary case, each of the output signals SP1 and SN1 of the output buffer 25 temporarily and transiently rises to around 2.0 V (i.e., around the power voltage of the RF circuit 10), and then lowers and finally converges to the common mode voltage Vcm1 (in this exemplary case, 1.0 V) ((A) of FIG. 3). At this time, since the switches 26P and 26N are each off state, the voltage of each of the signals SP2 and SN2 is maintained to the voltage Vcm2, and the voltage of each of the signals SP3 and SN3 is maintained to the bias voltage Vbias ((D) and (E) of FIG. 3).

Subsequently, at timing t2, the switch control section 13 changes the switch control signal SW2 from a high level to a low level ((B) of FIG. 3). Consequently, the switches 28P and 28N are each changed from the on state to the off state, so that each of the output terminals TOP and TON becomes in an electrically floating state, and the voltage of each of the signals SP2 and SN2 is maintained to the voltage Vcm2 ((D) of FIG. 3). Accordingly, the voltage of each of the input signals SP3 and SN3 to the demodulation circuit 50 is also maintained to the bias voltage Vbias ((E) of FIG. 3).

Subsequently, at timing t3, the switch control section 13 changes the switch control signal SW1 from the low level to the high level ((C) of FIG. 3). Consequently, the switches 26P and 26N are each changed from the off state to the on state, and the output terminals TOP and TON are connected to the output buffer 25. At this time, as illustrated in (D) of FIG. 3, the voltage of each of the output terminals TOP and TON (the voltage of each of the signals SP2 and SN2) is substantially not varied before and after the timing t3. Specifically, immediately before the timing t3, the common mode voltage Vcm1 as a voltage (the voltage of each of the signals SP1 and SN1, (A) of FIG. 3) of the first end of each of the switches 26P and 26N is substantially equal to the voltage Vcm2 (the voltage of each of the signals SP2 and SN2, (D) of FIG. 3) of the second end of each of the switches 26P and 26N. Hence, even if the switches 26P and 26N are each changed from the off state to the on state, the voltage of each of the signals SP2 and SN2 is substantially not varied. Accordingly, the voltage of each of the input signals SP3 and SN3 to the demodulation circuit 50 is also substantially not varied, and is maintained to the bias voltage Vbias ((E) of FIG. 3).

After that, the output buffer 25 of the RF circuit 10 supplies a differential signal to the demodulation circuit 50.

In this way, in the reception unit 1, the switch control section 13 sets each of the switches 26P and 26N to the off state, and then the power control section 12 starts power supply to the RF section 20. After a predetermined period has passed from start of the power supply to the RF section 20 by the power control section 12, the switch control section 13 turns on each of the switches 26P and 26N. Consequently, in the reception unit 1, even if the output signals SP1 and SN1 of the output buffer 25 are each transiently varied at power application (at the timing t1), it is possible to reduce a possibility of transmission of such a signal to the demodulation circuit 50, and thereby reduce a possibility of occurrence of degradation in properties or device failure in the demodulation circuit 50.

Furthermore, in the reception unit 1, the voltage of each of the output terminals TOP and TON is set to the voltage Vcm2 that is substantially equal to the common mode voltage Vcm1 of the output buffer 25 via the switches 28P and 28N, and then each of the switches 26P and 26N is changed from the off state to the on state. Hence, it is possible to reduce variation of the voltage of each of the output terminals TOP and TON at the timing t3 where each of the switches 26P and 26N is changed from the off state to the on state. Consequently, it is possible to reduce a possibility of occurrence of degradation in properties or device failure in the demodulation circuit 50.

Furthermore, in the reception unit 1, each of the switches 28P and 28N is changed from the on state into the off state, and then each of the switches 26P and 26N is changed from the off state to the on state. Hence, the switches 26P and 26N are not on at the same time with the switches 28P and 28N. Hence, even if the common mode voltage Vcm1 is different from the voltage Vcm2, it is possible to reduce a possibility of occurrence of a transient voltage variation in each of the output terminals TOP and TON due to such a voltage difference. Consequently, it is possible to reduce a possibility of occurrence of degradation in properties or device failure in the demodulation circuit 50.

### Comparative Example

A reception unit 1R according to a comparative example is now described. In this comparative example, the RF circuit is configured without providing the switches 26P and 26N and the like.

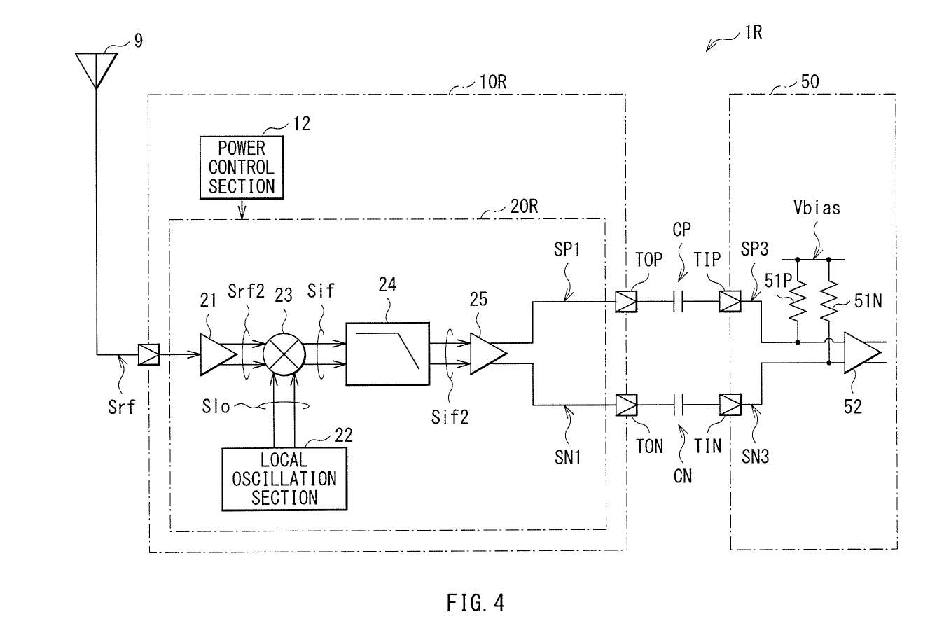

FIG. 4 illustrates an exemplary configuration of the reception unit 1R according to the comparative example. The reception unit 1R includes an RF circuit 10R. The RF circuit 10R is the same as the RF circuit 10 according to the above-described embodiment except that the switches 26P, 26N, 28P, and 28N, the resistors 27P and 27N, the voltage generation section 11, and the switch control section 13 are omitted.

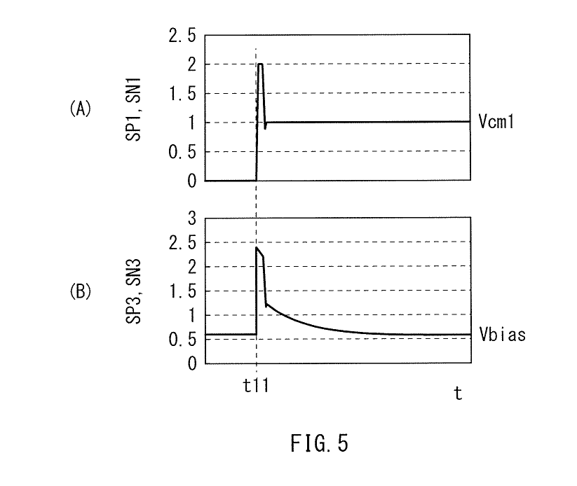

FIG. 5 illustrates operation of an RF section 20R at power application to the RF section 20R, where (A) illustrates a waveform of each of the signals SP1 and SN1, and (B) illustrates a waveform of each of the signals SP3 and SN3. At timing t11, the power control section 12 starts power supply to the RF section 20R. Consequently, as in the case of the above-described embodiment ((A) of FIG. 3), each of the output signals SP1 and SN1 of the output buffer 25 temporarily and transiently rises to around 2.0 V, and then lowers and finally converges to the common mode voltage Vcm1 ((A) of FIG. 5). At this time, such a transient signal is transmitted to the demodulation circuit 50 via the capacitors CP and CN. Specifically, as illustrated in (B) of FIG. 5, voltage of each of the signals SP3 and SN3 rises from the bias voltage Vbias to around 2.4 V at the timing t11, and then lowers and converges to the bias voltage Vbias.

Thus, in the reception unit 1R according to the comparative example, when each of the output signals SP1 and SN1 of the output buffer 25 is transiently varied at power application (at the timing t11), such a signal may be transmitted to the demodulation circuit 50. A protective diode is in general provided at an input/output terminal of an LSI in order to improve tolerance against electro-static discharge (ESD). However, such a protective diode may also not suppress the variation of a voltage depending on a signal waveform, and the voltage may be greatly varied as illustrated in FIG. 5. When such a high voltage is transmitted to the demodulation circuit 50, degradation in properties or device failure may occur in the demodulation circuit 50. In particular, when the demodulation circuit 50 is manufactured by a finer manufacturing process, more significant degradation in properties or the like may occur due to a low rating voltage.

In contrast, in the reception unit 1 according to the above-described embodiment, since the switches 26P and 26N and the like are provided, even if each of the output signals SP1 and SN1 of the output buffer 25 is transiently varied at power application (at the timing t11), it is possible to reduce a possibility of transmission of such a signal to the demodulation circuit 50 by turning off each of the switches 26P and 26N. Consequently, in the reception unit 1, it is possible to reduce a possibility of occurrence of degradation in properties or device failure in the demodulation circuit 50.

[Effects]

As described above, in the above-described embodiment, since the switches 26P and 26N are provided, even if each of the output signals of the output buffer 25 is transiently varied, it is possible to reduce a possibility of transmission of such a signal to a subsequent-stage circuit. Consequently, it is possible to reduce a possibility of occurrence of degradation in properties or device failure in the subsequent-stage circuit.

Furthermore, in the above-described embodiment, voltage of the output terminal is set to the voltage Vcm2 that is substantially equal to the common mode voltage Vcm1 of the output buffer, and then each of the switches 26P and 26N is changed from the off state to the on state. It is therefore possible to reduce a possibility of occurrence of degradation in properties or device failure in the subsequent-stage circuit.

Furthermore, in the above-described embodiment, each of the switches 28P and 28N is changed from the on state to the off state, and then each of the switches 26P and 26N is changed from the off state to the on state. Hence, the switches 26P and 26N are not on at the same time with the switches 28P and 28N. It is therefore possible to reduce a possibility of occurrence of degradation in properties or device failure in the subsequent-stage circuit.

[Modification 1]

While the common mode voltage Vcm1 and the voltage Vcm2 are substantially equal to each other in the above-described embodiment, this is not limitative. The voltages Vcm1 and Vcm2 may be different from each other to the extent where degradation in properties does not occur in the subsequent-stage circuit.

[Modification 2]

While each of the switches 28P and 28N is changed from the on state to the off state, and then each of the switches 26P and 26N is changed from the off state to the on state in the above-described embodiment, this is not limitative. Alternatively, for example, each of the switches 28P and 28N may be changed from the on state to the off state at the same timing as the timing at which each of the switches 26P and 26N is changed from the off state to the on state.

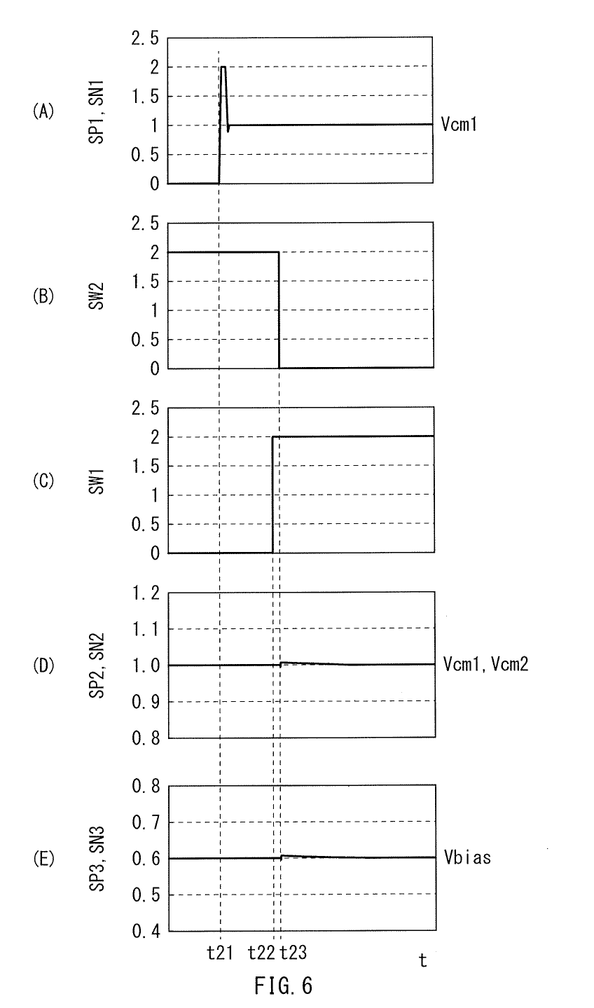

Alternatively, for example, as illustrated in FIG. 6, each of the switches 28P and 28N may be changed from the on state to the off state at timing t23 after each of the switches 26P and 26N is changed from the off state to the on state at timing t22. In this case, the switches 26P and 26N are on at the same time with the switches 28P and 28N in a period from the timing t22 to the timing t23. Consequently, for example, when the common mode voltage Vcm1 is different from the voltage Vcm2, a current may flow via the switch 26P, the resistor 27P, and the switch 28P, and a current may flow via the switch 26N, the resistor 27N, and the switch 28N between the voltage generation section 11 and the output buffer 25 during such a period. As a result, a transient voltage variation may occur in each of the output terminals TOP and TON. Hence, in such a case, the resistance value of each of the resistors 27P and 27N is necessary to be appropriately set. Such appropriate setting of the resistance value makes it possible to reduce a possibility of occurrence of voltage variation in each of the output terminals TOP and TON.

[Modification 3]

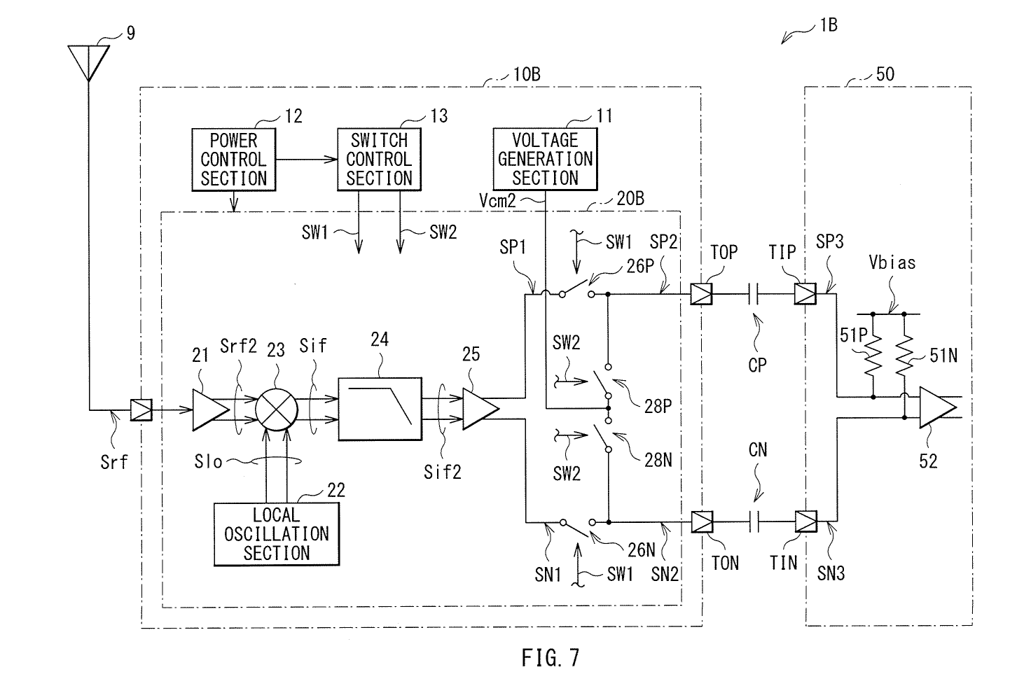

While the resistors 27P and 27N are provided in the above-described embodiment, this is not limitative. Alternatively, for example, as in a reception unit 1B illustrated in FIG. 7, such resistors 27P and 27N may be omitted. In this case, the switches 26P and 26N are desirably not on at the same time with the switches 28P and 28N.

[Modification 4]

While the switches 26P, 26N, 28P, and 28N are each turned on or off at power application in the above-described embodiment, this is not limitative. Alternatively, the switches 26P, 26N, 28P, and 28N may each be turned on or off in any of various cases where each of the output signals SP1 and SN1 of the output buffer 25 is transiently varied. For example, when the RF circuit 10 has a function of adjusting properties, i.e., has a so-called calibration function, this technology may be applicable to a case where each of the output signals SP1 and SN1 of the output buffer 25 is transiently varied due to such calibration operation. Specifically, for example, in the case where gain of the LNA 21 or the output buffer 25 is altered by calibration, each of the output signals SP1 and SN1 of the output buffer 25 may be transiently varied. In such a case, the switches 26P, 26N, 28P, and 28N are each turned on or off as in the above-described embodiment, thereby it is possible to reduce a possibility of transmission of such a signal to a subsequent-stage circuit, and consequently possible to reduce a possibility of occurrence of degradation in properties or device failure in the subsequent-stage circuit.

Although the present application has been described with the example embodiment and the Modifications thereof hereinbefore, the technology is not limited thereto, and various modifications or alterations thereof may be made.

For example, although the technology is applied to the reception unit that receives radio signals in the above-described embodiment and the Modifications, the technology is not limited thereto and may be applicable to any of signal transmission applications through AC coupling.

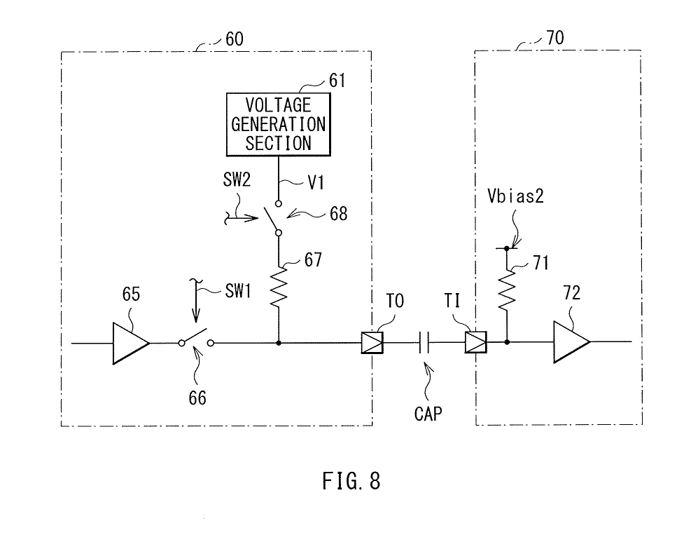

Furthermore, for example, although the technology is applied to an application of transmission of a differential signal in the above-described embodiment and the Modifications, the technology is not limited thereto and may be applicable to an application of transmission of a single-phase signal. FIG. 8 illustrates an example in such a case. In this example, the transmission circuit 60 transmits a single-phase signal to a reception circuit 70 through AC coupling via a capacitor CAP. The transmission circuit 60 includes a voltage generation section 61, an output buffer 65, a switch 66, a resistor 67, and a switch 68. The voltage generation section 61 generates a voltage V1. The output buffer 65 is a buffer that outputs an analog signal of which the DC level is a voltage V2 that is substantially equal to the voltage V1. The switch 66 is a switch that is turned on or off based on a switch control signal SW1, and has a first end connected to an output end of the output buffer 65, and a second end that is connected to a first end of the capacitor CAP via an output terminal TO of the transmission circuit 60 and to a first end of the resistor 67. The resistor 67 has the first end connected to a second end of the switch 66 and to the first end of the capacitor CAP via the output terminal TO, and a second end connected to a first end of the switch 68. The switch 68 is a switch that is turned on or off based on a switch control signal SW2, and has a first end connected to a second end of the resistor 67, and a second end to which the voltage V1 is supplied from the voltage generation section 61. The reception circuit 70 includes a resistor 71 and an input buffer 72. The resistor 71 is a resistor supplying a bias voltage Vbias2 to an input terminal of the input buffer 72, and has a first end connected to a second end of the capacitor CAP via an input terminal TI of the reception circuit 70, and has a second end to which the bias voltage Vbias2 is supplied. The input buffer 72 receives a signal of the input terminal TI.

Furthermore, for example, in the above-described embodiment and the Modifications, the resistor 27P and the switch 28P are configured such that the resistor 27P is connected to the output terminal TOP, and the switch 28P is connected to the voltage generation section 11. Similarly, the resistor 27N and the switch 28N are configured such that the resistor 27N is connected to the output terminal TON, and the switch 28N is connected to the voltage generation section 11. However, these are not limitative. Alternatively, the resistor 27P and the switch 28P may be configured such that the resistor 27P is connected to the voltage generation section 11, and the switch 28P is connected to the output terminal TOP. Similarly, the resistor 27N and the switch 28N may be configured such that the resistor 27N is connected to the voltage generation section 11, and the switch 28N is connected to the output terminal TON.

It is to be noted that the effects described in this specification are merely exemplified and not limitative, and other effects may be shown.

It is possible to achieve at least the following configurations from the above-described example embodiments of the disclosure.

(1) A signal output circuit, including:

an output buffer including a first terminal configured to output a first output signal;

a first output terminal;

a first switch inserted on a signal path from the first terminal to the first output terminal; and

a second switch configured to transmit a predetermined voltage to the first output terminal when being turned on.

(2) The signal output circuit according to (1), further including:

a voltage generation section configured to generate the predetermined voltage; and

a resistor provided in series to the second switch between the voltage generation section and the first output terminal.

(3) The signal output circuit according to (1) or (2), further including a control section configured to control the first switch to be off and control the second switch to be on for a predetermined period, and thereafter perform operation of turning on the first switch and operation of turning off the second switch.
(4) The signal output circuit according to (3), wherein the control section turns on the first switch at timing after timing of turning off the second switch.
(5) The signal output circuit according to (3), wherein the control section turns on the first switch, and then turns off the second switch.
(6) The signal output circuit according to any one of (3) to (5), wherein the first output signal is transiently varied within the predetermined period.
(7) The signal output circuit according to any one of (3) to (6), wherein power application to the output buffer is performed within the predetermined period.
(8) The signal output circuit according to any one of (3) to (6), wherein calibration operation is performed within the predetermined period.
(8) The signal output circuit according to any one of (1) to (8), wherein the first output terminal is connected to a subsequent-stage circuit via a capacitor.
(10) The signal output circuit according to (1), further including a second output terminal, a third switch, and a fourth switch, wherein
the output buffer further includes a second terminal configured to generate a second output signal configuring a differential signal together with the first output signal,

the third switch is inserted on a signal path from the second terminal to the second output terminal, and

the fourth switch is configured to supply the predetermined voltage to the second output terminal when being turned on.

(11) The signal output circuit according to (10), further including:

a voltage generation section configured to generate the predetermined voltage;

a first resistor provided in series to the second switch between the voltage generation section and the first output terminal; and

a second resistor provided in series to the fourth switch between the voltage generation section and the second output terminal.

(12) The signal output circuit according to (10) or (11), wherein the predetermined voltage is substantially equal to a common mode voltage of the differential signal.
(13) A signal output method, including:

outputting a first output signal from a first terminal of an output buffer;

controlling a first switch to be off for a predetermined period, the first switch being inserted on a signal path from the first terminal to a first output terminal, and controlling a second switch to be on for the predetermined period, the second switch being configured to supply a predetermined voltage to the first output terminal when being turned on; and

thereafter performing operation of turning on the first switch and operation of turning off the second switch.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A signal output circuit, comprising:
an output buffer including a first terminal configured to output a first output signal;
a first output terminal;
a first switch inserted on a signal path from the first terminal to the first output terminal; and
a second switch configured to transmit a predetermined voltage to the first output terminal when being turned on.

2. The signal output circuit according to claim 1, further comprising:
a voltage generation section configured to generate the predetermined voltage; and
a resistor provided in series to the second switch between the voltage generation section and the first output terminal.

3. The signal output circuit according to claim 1, further comprising a control section configured to control the first switch to be off and control the second switch to be on for a predetermined period, and thereafter perform operation of turning on the first switch and operation of turning off the second switch.

4. The signal output circuit according to claim 3, wherein the control section turns on the first switch at timing after timing of turning off the second switch.

5. The signal output circuit according to claim 3, wherein the control section turns on the first switch, and then turns off the second switch.

6. The signal output circuit according to claim 3, wherein the first output signal is transiently varied within the predetermined period.

7. The signal output circuit according to claim 3, wherein power application to the output buffer is performed within the predetermined period.

8. The signal output circuit according to claim 3, wherein calibration operation is performed within the predetermined period.

9. The signal output circuit according to claim 1, wherein the first output terminal is connected to a subsequent-stage circuit via a capacitor.

10. The signal output circuit according to claim 1, further comprising a second output terminal, a third switch, and a fourth switch, wherein
the output buffer further includes a second terminal configured to generate a second output signal configuring a differential signal together with the first output signal,
the third switch is inserted on a signal path from the second terminal to the second output terminal, and
the fourth switch is configured to supply the predetermined voltage to the second output terminal when being turned on.

11. The signal output circuit according to claim 10, further comprising:
a voltage generation section configured to generate the predetermined voltage;
a first resistor provided in series to the second switch between the voltage generation section and the first output terminal; and
a second resistor provided in series to the fourth switch between the voltage generation section and the second output terminal.

12. The signal output circuit according to claim 10, wherein the predetermined voltage is substantially equal to a common mode voltage of the differential signal.

13. A signal output method, comprising:
outputting a first output signal from a first terminal of an output buffer;
controlling a first switch to be off for a predetermined period, the first switch being inserted on a signal path from the first terminal to a first output terminal, and controlling a second switch to be on for the predetermined period, the second switch being configured to supply a predetermined voltage to the first output terminal when being turned on; and
thereafter performing operation of turning on the first switch and operation of turning off the second switch.
